(19) United States
(12) Patent Application Publication
(10) Pub. No.: US 2014/0360582 A1
(43) Pub. Date: Dec. 11, 2014

(54) THIN FILM PHOTOVOLTAIC MODULE WITH STABILIZED POLYMER

(71) Applicant: SOLUTIA INC., St. Louis, MO (US)

(72) Inventors: Weihong Cui, Longmeadow, MA (US); Steven V. Haldeman, Hampden, MA (US)

(73) Assignee: SOLUTIA INC., St. Louis, MO (US)

(21) Appl. No.: 14/467,683

(22) Filed: Aug. 25, 2014

Related U.S. Application Data
(63) Continuation-in-part of application No. 12/356,462, filed on Jan. 20, 2009, now abandoned.

(51) Int. Cl. H01L 31/048; C08K 5/3475

(52) U.S. Cl. CPC H01L 31/0481; H01L 31/0487; C08K 5/3475
USPC 136/259

(57) ABSTRACT

The present invention provides a photovoltaic device comprising metal and a poly(vinyl butyral) layer that incorporates a suitable amount of 1H-benzotriazole. When electrical bias is applied to the photovoltaic device, 1H-benzotriazole forms a barrier layer at the metal/poly(vinyl butyral) interface, which, for example, unexpectedly virtually eliminated the yellowing of poly(vinyl butyral) in photovoltaic devices comprising silver components.

### CROSS REFERENCE TO RELATED APPLICATION

This application is a continuation-in-part of U.S. application Ser. No. 12/356,462 filed on Jan. 20, 2009, now United States Publication No. 2010-0180940; all of which is incorporated herein by reference

### FIELD OF THE INVENTION

The present invention is in the field of photovoltaic modules, and, specifically, the present invention is in the field of thin film photovoltaic modules incorporating a polymer layer and a photovoltaic device on a suitable thin film photovoltaic substrate.

### BACKGROUND

There are two common types of photovoltaic (solar) modules in use today. The first type of photovoltaic module utilizes a semiconductor wafer as a substrate and the second type of photovoltaic module utilizes a thin film of semiconductor that is deposited on a suitable substrate.

Semiconductor wafer type photovoltaic modules typically comprise the crystalline silicon wafers that are commonly used in various solid state electronic devices, such as computer memory chips and computer processors.

Thin film photovoltaics can incorporate one or more conventional semiconductors, such as amorphous silicon, on a suitable substrate. Unlike wafer applications, in which a wafer is cut from an ingot, thin film photovoltaics are formed using comparatively simple deposition techniques such as sputter coating, physical vapor deposition (PVD), or chemical vapor deposition (CVD).

Thin film photovoltaic modules typically incorporate a layer of ethylene vinyl acetate copolymer (EVA) or a layer of poly(vinyl butyral)(PVB) to seal and protect the underlying photovoltaic device. The long term reliable functioning of the photovoltaic module is, of course, of paramount importance, and, accordingly, polymer layer stability is a critical factor for any particular photovoltaic device.

While EVA has been used extensively in photovoltaic modules, the use of poly(vinyl butyral) is very desirable because it does not suffer from the same drawbacks as EVA, such as acetic acid degradation, as detailed in U.S. Patent Publication 2007/0259998.

While it is often preferable to employ poly(vinyl butyral), poly(vinyl butyral) has been observed to yellow when in contact with silver-containing elements.

Accordingly, what are needed in the art are poly(vinyl butyral) compositions that are suitable for stable, long term use in photovoltaic modules having metal elements.

### SUMMARY OF THE INVENTION

The present invention provides a photovoltaic device comprising metal and a poly(vinyl butyral) layer that incorporates a suitable amount of 1H-benzotriazole. When electrical bias is applied to the photovoltaic device, 1H-benzotriazole forms a barrier layer at the metal/poly(vinyl butyral) interface, which, for example, unexpectedly virtually eliminated the yellowing of poly(vinyl butyral) in photovoltaic devices comprising silver components.

### BRIEF DESCRIPTION OF THE DRAWINGS

FIG. 1 represents a schematic cross sectional view of a thin film photovoltaic device of the present invention.

### DETAILED DESCRIPTION

Thin film photovoltaic devices of the present invention include a poly(vinyl butyral) layer formulated according to the description herein, which provides excellent adhesion, resistivity, sealing, processability, and durability to the photovoltaic device, and which comprises 1H-benzotriazole.

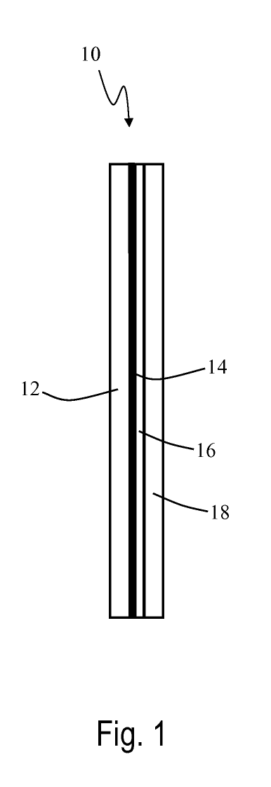

One embodiment of a thin film photovoltaic module of the present invention is shown in FIG. 1 generally at 10. As shown in the FIGURE, a photovoltaic device 14 is formed on a base substrate 12, which can be, for example, glass or plastic. A protective substrate 18 is bound to the photovoltaic device 14 with a poly(vinyl butyral) layer 16.

As used herein, “1H-benzotriazole” refers to the compound shown in the following formula:

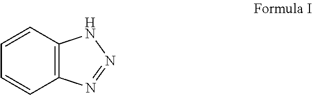

1H-benzotriazole can be included in the poly(vinyl butyral) layer in any suitable amount, and, in various embodiments, 1H-benzotriazole is included, as a weight percent, at 0.001 to 5%, 0.01 to 5%, 0.1 to 5%, 1 to 5%, 2 to 5%, or 0.1 to 0.4% or 0.01% to 0.06%, 0.01% to 0.05%, 0.01% to 0.08%, 0.1 to 5%, 0.1 to 3.5%, 0.1 to 1%, 0.1 to 2%, 0.01 to 3.5%, 0.01 to 2.5%, 0.01% to 1.5%, 0.01 to 2%, 0.04% to 1%, 0.03% to 0.06%, 0.04% to 0.06%, 0.04% to 0.05%, 0.01% to 0.2%, 0.01% to 0.3%, 0.01% to 0.4%, or 0.01% to 0.5%, or 0.01 to 1.1% or 0.01 to 1.2%, or 0.01 to 1.3%, or 0.02 to 1.1%, or 0.02 to 1.1% or 0.03 to 1.1% or 0.03 to 1.2% or 0.03 to 1.3%.

In further embodiments of the invention, when the laminate is manufactured from the poly(vinyl butyral) layer comprising 1H-benzotriazole, the haze value of the laminate is less than 1.0%, less than 0.9%, less than 0.8%, less than 0.7%, less than 0.6%, less than 0.5%, less than 0.4%, or less than 0.3%. Haze is defined as the percentage of light that is deflected more than 2.5 degrees from the incoming light direction. The ASTM standard for the haze value test is ASTM D1003-11, Procedure B.

In further embodiments of the invention, when the laminate is manufactured from the poly(vinyl butyral) layer comprising 1 H-benzotriazole, the yellowness index is less than 100 or less than 90, or less than 80, or less than 70 or less than 60, or less than 50 or less than 40, or less than 30 or less than 25 or less than 20. The yellowness index measurement technique is describe subsequently is this disclosure.

1H-benzotriazole is preferably included in the poly(vinyl butyral) at the time of formation of a polymer layer through melt compounding the 1H-benzotriazole with the poly(vinyl butyral) resin and any other additives. 1H-benzotriazole can also be provided in salt form, for example, sodium, potassium, and ammonium.

1H-benzotriazole is a well-known corrosion inhibitor for copper, silver, cobalt, aluminum and zinc. It is commercially available from the PMC Specialties Group, and is sold under the trade name Cobratec-99. Other corrosion inhibitors that are useful in photovoltaic devices of the present invention include: derivatives of 1H-benzotriazole such as 5-methyl-1H-benzotriazole, 5-carboxybenzotriazole, and other alkyl derivative of 1H-benzotriazole; imidazole and imidazole derivatives such as benzimidizole, 5,6-dimethylbenzimdiazole, 2-mercaptobenzoimidazole, and fatty acid derivatives of 4,5-dihydro-1H-imidazole; thiadiazole and alkyl derivatives of thiadiazole such as 2-mercaptobenzothiazole, 1,2-bis(phenylthio)ethane, 2,5-bis(n-octyldithio)-1,3,4-thiadiazole, 2-amino, 5-mercapto, 1,3,4-thiadizole, 2-mercaptopyrimidine, 2-mercaptobenzoxazole; histamine; histidine; and 2-aminopyrimidine.

### Further Additives

Further additives that can be included in polymer layers of the present invention to improve stability and performance include metal deactivators such as Irganox MD-1024° (CAS 32687-78-8) and Naugard XL-1® (CAS 70331-94-1), hindered amine light stabilizers such as Tinuvin 123® (CAS129757-67-1), and phenolic antioxidants such as Anox 70® (2,2′-thiodiethylene bis[3-(3,5-di-t-butyl-4-hydroxyphenyl)propionate] CAS 41484-35-9).

Combination of any of the above polymer stabilizers with benzotriazole is expected to achieve further stability of poly(vinyl butyral) both at the poly(vinyl butyral)-metal interface and inside the polymer. Experimental data has suggested that adding both benzotriazole and Anox 70® into a poly(vinyl butyral) formulation indeed further reduces the polymer discoloration and protects the structure of thin-film solar panels. In various embodiments of the present invention, 1H-benzotriazole and a phenolic antioxidants are incorporated into a poly(vinyl butyral) layer, and, in some embodiments, 1H-benzotriazole and 2,2′-thiodiethylene bis[3-(3,5-di-t-butyl-4-hydroxyphenyl)propionate are incorporated into a poly(vinyl butyral) layer.

Poly(Vinyl Butyral) Layer

The thin film photovoltaic modules of the present invention utilize a layer of poly(vinyl butyral) as a laminating adhesive that is used to seal the photovoltaic device to a protective substrate, thereby forming the photovoltaic module of the present invention.

Poly(vinyl butyral) of the present invention can be produced by acetalization processes, as are known to those skilled in the art (see, for example, U.S. Pat. Nos. 2,282,057 and 2,282,026). In one embodiment, the solvent method described in Vinyl Acetal Polymers, in Encyclopedia of Polymer Science & Technology, 3^{rd} edition, Volume 8, pages 381-399, by B. E. Wade (2003) can be used. In another embodiment, the aqueous method described therein can be used. Poly(vinyl butyral) is commercially available in various forms from, for example, Solutia Inc., St. Louis, Mo. as Butvar™ resin.

In various embodiments, the poly(vinyl butyral) comprises 10 to 35 weight percent (wt. %) hydroxyl groups calculated as poly(vinyl alcohol), 13 to 30 wt. % hydroxyl groups calculated as poly(vinyl alcohol), or 15 to 22 wt. %

hydroxyl groups calculated as poly(vinyl alcohol). The polymer layer resin can also comprise less than 15 wt. % residual ester groups, 13 wt. %, 11 wt. %, 9 wt. %, 7 wt. %, 5 wt. %, or less than 3 wt. % residual ester groups calculated as polyvinyl acetate, with the balance being an acetal, preferably butyraldehyde acetal, but optionally including other acetal groups in a minor amount, for example, a 2-ethyl hexanal group (see, for example, U.S. Pat. No. 5,137,954).

In various embodiments, the poly(vinyl butyral) has a molecular weight of at least 30,000, 40,000, 50,000, 55,000, 60,000, 65,000, 70,000, 120,000, 250,000, or at least 350,000 grams per mole (g/mole or Daltons). Small quantities of a dialdehyde or trialdehyde can also be added during the acetalization step to increase molecular weight to at least 350,000 g/mole (see, for example, U.S. Pat. Nos. 4,902,464; 4,874,814; 4,814,529; and, 4,654,179). As used herein, the term “molecular weight” means the weight average molecular weight.

Various adhesion control agents can be used in polymer layers of the present invention, including sodium acetate, potassium acetate, and magnesium salts. Magnesium salts that can be used with these embodiments of the present invention include, but are not limited to, those disclosed in U.S. Pat. No. 5,728,472, such as magnesium salicylate, magnesium nicotinate, magnesium di-(2-aminobenzoate), magnesium di-(3-hydroxy-2-napthoate), and magnesium bis(2-ethyl butyrate) (chemical abstracts number 79992-76-0). In various embodiments of the present invention the magnesium salt is magnesium bis(2-ethyl butyrate).

In various embodiments of polymer layers of the present invention, the polymer layers can comprise 20 to 60, 25 to 60, 20 to 80, 10 to 70, or 10 to 100 parts plasticizer phr. Of course other quantities can be used as is appropriate for the particular application. In some embodiments, the plasticizer has a hydrocarbon segment of fewer than 20, fewer than 15, fewer than 12, or fewer than 10 carbon atoms. The amount of plasticizer can be adjusted to affect the glass transition temperature (T_{g}) of the poly(vinyl butyral) layer. In general, higher amounts of plasticizer are added to decrease the T_{g}.

Any suitable plasticizers can be added to the polymer resins of the present invention in order to form the polymer layers. Plasticizers used in the polymer layers of the present invention can include esters of a polybasic acid or a polyhydric alcohol, among others. Suitable plasticizers include, for example, triethylene glycol di-(2-ethylbutyrate), triethylene glycol di-(2-ethylhexanoate), triethylene glycol diheptanoate, tetraethylene glycol diheptanoate, dihexyl adipate, dioctyl adipate, hexyl cyclohexyladipate, mixtures of heptyl and nonyl adipates, diisononyl adipate, heptylnonyl adipate, dibutyl sebacate, polymeric plasticizers such as the oil-modified sebacic alkyds, mixtures of phosphates and adipates such as disclosed in U.S. Pat. No. 3,841,890, adipates such as disclosed in U.S. Pat. No. 4,144,217, and mixtures and combinations of the foregoing. Other plasticizers that can be used are mixed adipates made from C₄ to C₉ alkyl alcohols and cyclo C₄ to C₁₀ alcohols, as disclosed in U.S. Pat. No. 5,013,779, and C₆ to C₈ adipate esters, such as hexyl adipate. In various embodiments, the plasticizer used is dihexyl adipate and/or triethylene glycol di-2 ethylhexanoate.

The poly(vinyl butyral) polymer, plasticizer, and any additives can be thermally processed and configured into sheet form according to methods known to those of ordinary skill in the art. One exemplary method of forming a poly(vinyl butyral) sheet comprises extruding molten poly(vinyl butyral) comprising resin, plasticizer, and additives by forcing the melt through a die (for example, a die having an opening that is substantially greater in one dimension than in a perpendicular dimension). Another exemplary method of forming a poly(vinyl butyral) sheet comprises casting a melt from a die onto a roller, solidifying the resin, and subsequently removing the solidified resin as a sheet. In various embodiments, the polymer layers can have thicknesses of, for example, 0.1 to 2.5 millimeters, 0.2 to 2.0 millimeters, 0.25 to 1.75 millimeters, and 0.3 to 1.5 millimeters.

The poly(vinyl butyral) layers of the present invention can include low molecular weight epoxy additives. Any suitable epoxy agent can be used with the present invention, as are known in the art (see, for example, U.S. Pat. Nos. 5,529,848 and 5,529,849).

Other additives may be incorporated into the polymer sheet to enhance its performance in a final product. Such additives include, but are not limited to, dyes, pigments, stabilizers (e.g., ultraviolet stabilizers), antioxidants, antiblock agents, additional IR absorbers, flame retardants, combinations of the foregoing additives, and the like, as are known in the art.

Typical ultraviolet stabilizers include substituted 2H-benzotriazoles, such as those sold by Ciba Specialty Company under the trade name Tinuvin®, for example, Tinuvin 328®, as shown in Formula II:

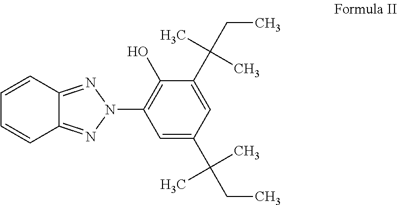 [SMILES: CCC(C)(C)c1cc(-n2nc3ccccc3n2)c(O)c(C(C)(C)CC)c1]

### Base Substrate

Base substrates of the present invention, which are shown as element 12 in FIG. 1, can be any suitable substrate onto which the photovoltaic devices of the present invention can be formed. Examples include, but are not limited to, glass, and rigid plastic glazing materials which yield “rigid” thin film modules, and thin plastic films such as poly(ethylene terephthalate), polyimides, fluoropolymers, and the like, which yield “flexible” thin film modules. It is generally preferred that the base substrate allow transmission of most of the incident radiation in the 350 to 1,200 nanometer range, but those of skill in the art will recognize that variations are possible, including variations in which light enters the photovoltaic device through the protective substrate.

### Thin Film Photovoltaic Device

Thin film photovoltaic devices of the present invention, which are shown as element 14 in FIG. 1, are formed directly on the base substrate. Typical device fabrication involves the deposition of a first conductive layer, etching of the first conductive layer, deposition and etching of semiconductive layers, deposition of a second conductive layer, etching of the second conductive layer, and application of bus conductors and protective layers, depending on the application. An electrically insulative layer can optionally be formed on the base substrate between the first conductive layer and the base substrate. This optional layer can be, for example, a silicon layer.

While the 1H-benzotriazole agent of the present invention can be added to polymer layers for use on photovoltaic devices devoid of any silver, in preferred embodiments, 1H-benzotriazole is used in a poly(vinyl butyral) layer that is used in a photovoltaic module having a photovoltaic device that comprises silver. Examples of silver components include, but are not limited to, conducting layers or elements (such as wire grid) or reflecting layers (see, for example, US2006/0213548).

In other embodiments, the 1H-benzotriazole agent of the present invention can be added to polymer layers for use on photovoltaic devices comprising other metals that are subject to degradation, including, for example, bismuth, copper, cadmium, lead, tin, zinc, gold, indium, palladium, platinum, aluminum, antimony, chromium, iron, nickel, rhodium, tantalum, titanium, or vanadium.

It will be recognized by those of skill in the art that the foregoing description of device fabrication is but one known method and is but one embodiment of the present invention. Many other types of thin film photovoltaic devices are within the scope of the present invention. Examples of formation methods and devices include those described in U.S. Pat. Nos. 2003/0180983, 7,074,641, 6,455,347, 6,500,690, 2006/0005874, 2007/0235073, 7,271,333, and 2002/0034645.

The various components of the thin film photovoltaic device can be formed through any suitable method. In various embodiments chemical vapor deposition (CVD), physical vapor deposition (PVD), and/or sputtering can be used.

The two conductive layers described above serve as electrodes to carry the current generated by the interposed semiconductor material. One of the electrodes typically is transparent to permit solar radiation to reach the semiconductor material. Of course, both conductors can be transparent, or one of the conductors can be reflective, resulting in the reflection of light that has passed through the semiconductor material back into the semiconductor material. Conductive layers can comprise any suitable conductive oxide material, such as tin oxide or zinc oxide, or, if transparency is not critical, such as for “back” electrodes, metal or metal alloy layers, such as those comprising aluminum or silver, can be used. In other embodiments, a metal oxide layer can be combined with the metal layer to form an electrode, and the metal oxide layer can be doped with boron or aluminum and deposited using low-pressure chemical vapor deposition. The conductive layers can be, for example, from 0.1 to 10 micrometers in thickness.

The photovoltaic region of the thin film photovoltaic device can comprise, for example, hydrogenated amorphous silicon in a conventional PIN or PN structure. The silicon can be typically up to about 500 nanometers in thickness, typically comprising a p-layer having a thickness of 3 to 25 nanometers, an i-layer of 20 to 450 nanometers, and an n-layer of 20 to 40 nanometers. Deposition can be by glow discharge in silane or a mixture of silane and hydrogen, as described, for example, in U.S. Pat. No. 4,064,521.

Alternatively, the semiconductor material may be micromorphous silicon, cadmium telluride (CdTe or CdS/CdTe), copper indium diselenide, (CuInSe₂, or “CIS”, or CdS/CuInSe₂), copper indium gallium selenide (CuInGaSe₂, or “GIGS”), or other photovoltaically active materials. Photovoltaic devices of this invention can have additional semiconductor layers, or combinations of the foregoing semiconductor types, and can be a tandem, triple-junction, or heterojunction structure.

Etching of the layers to form the individual components of the device can be performed using any conventional semiconductor fabrication technique, including, but not limited to, silkscreening with resist masks, etching with positive or negative photoresists, mechanical scribing, electrical discharge scribing, chemical etching, or laser etching. Etching of the various layers will result, typically, in the formation of individual photocells within the device. Those devices can be electrically connected to other devices using bus bars that are inserted or formed at any suitable stage of the fabrication process.

A protective layer can optionally be formed over the photocells prior to assembly with the poly(vinyl butyral) layer and the protective substrate. The protective layer can be, for example, sputtered aluminum.

The electrically interconnected photocells formed from the optional insulative layer, the conductive layers, the semiconductor layers, and the optional protective layer form the photovoltaic device of the present invention.

### Protective Substrate

Protective substrates of the present invention, which are shown as element 18 in FIG. 1, can be any suitable substrate that can be used to bond to the polymer layer and sufficiently protect the underlying device. Examples include, but are not limited to, glass, rigid plastic, and thin plastic films such as poly(ethylene terephthalate), polyimides, fluoropolymers, and the like. It is generally preferred that the protective substrate allow transmission of most of the incident radiation in the 350 to 1,200 nanometer range, but those of skill in the art will recognize that variations are possible, including variations in which all of the light entering the photovoltaic device enters through the base substrate. In these embodiments, the protective substrate does not need to be transparent, or mostly so, and can be, for example, a reflective film that prevents light from exiting the photovoltaic module through the protective substrate.

### Assembly

Final assembly of thin film photovoltaic modules of the present invention involves disposing a poly(vinyl butyral) layer in contact with a thin film photovoltaic device, with bus bars, if applicable, that has been formed on a base substrate, disposing a protective substrate in contact with the poly(vinyl butyral) layer, and laminating the assembly to form the module.

While the main body of this application has been drafted with the preferred embodiment exemplified, the present invention includes within its scope all photovoltaic devices comprising a silver component and poly(vinyl butyral), including standard (non-thin film) photovoltaic devices, as well as other multilayer laminates comprising a polyvinyl butyral sheet in contact with a degradable metal component (e.g., solar glazings, and mirrors), which are well known in the art.

The present invention includes poly(vinyl butyral) sheets having any of the components described herein incorporating 1H-benzotriazole and, optionally, any further additives as described herein.

The present invention includes a method of making a photovoltaic module, comprising the steps of providing a base substrate, forming a photovoltaic device of the present invention thereon, and laminating the photovoltaic device to a protective substrate using a poly(vinyl butyral) layer of the present invention.

The present invention includes photovoltaic modules comprising polymer layers of the present invention.

### EXAMPLES

### Example 1

Using a small lab scale extruder, 750 grams of poly(vinyl butyral) resin with a vinyl alcohol content of about 18.7 wt % and a vinyl acetate residue of 0.5-4 wt % are mixed with 285 grams of triethylene glycol di-(2-ethylhexanoate) as plasticizer, 2.63 grams of the UV absorber Tinuvin 328®, 0.19 gram of magnesium (2-ethylbutyrate) as an adhesion control salt, and various additives as shown in Table 1, and extruded into 0.76 millimeter thick sheets.

The sheets are used to laminate a thin-film solar cell (15×15 centimeters). The laminates are exposed to 85° C. at 85% relative humidity under a 1,000 volt bias for 1,000 hours. The yellowness indices of the laminates are measured following the 1,000 hour exposure. The typical yellowness index of the laminates prior to exposure is about 12 (between 11 and 13).

TABLE 1

| | | | Yellowness |
|---|---|---|---|
| Sample | | Weight | Index after |
| No. | Additive | additive | 1,000 hrs |
| Control #1 | None | None | 122.2 |
| 1 | 1H-Benzotriazole | 1.875 grams | 27.1 |
| 2 | Anox 70 ® (2,2′-thiodiethylene | 1.875 grams | 93.4 |
| | bis[3-(3,5-di-t-butyl-4- | | |
| | hydroxyphenyl)propionate]) | | |
| 3 | Naugard XL-1 ® (CAS 70331- | 1.875 grams | 118.4 |
| | 94-1) benzenepropanoic acid, | | |
| | 3,5-bis(1,1-dimethylethyl)-4- | | |
| | hydroxy-, 1,1′-[(1,2-dioxo-1,2- | | |
| | ethanediyl)bis(imino-2,1- | | |
| | ethanediyl)] ester | | |
| Control #2 | None | None | 110.8 |
| 4 | Irganox MD1024 ® | 0.75 grams | 61.6 |
| | benzenepropanoic acid, 3,5- | | |
| | bis(1,1-dimethylethyl)-4- | | |
| | hydroxy-, 2-[3-[3,5-bis(1,1- | | |
| | dimethylethyl)-4- | | |
| | hydroxyphenyl]-1- | | |
| | oxopropyl]hydrazide (CAS | | |
| | 32687-78-8) | | |
| | Tinuvin 123 ® decanedioic ac- | 0.75 grams | |
| | id, 1,10-bis[2,2,6,6-tetramethyl- | | |
| | 1-(octyloxy)-4-piperidinyl] | | |
| | ester (CAS 122586-52-1) | | |

### Example 2

Sheets (1.14 mm thick) are prepared as followed in a pilot scale extruder: for every 100 grams of poly(vinyl butyral) resin, 38 grams of triethylene glycol di-(2-ethylhexanoate) as plasticizer, 0.35 grams Tinuvin 328®, 0.025 grams magnesium (2-ethylbutyrate), and various additives as shown in Table 2 are added. Glass coated with silver and other layers are used for preparing the poly(vinyl butyral) laminates. The size of the coated glass is 7×9 centimeters. The laminates are tested for 670 hours under 85° C., 85% relative humidity (RH) and 1,000 volts of electrical bias.

TABLE 2

| | Poly(vinyl butyral) formulation | Yellowness Index | |
|---|---|---|---|
| Sample | (per 100 grams poly(vinyl | | t = 670 |
| No. | butyral) resin) | t = 0 | hours |
| Control 3 | Control (no additional additive) | 12.8 | 95.6 |
| 5 | 0.125 g 1H Benzotriazole | 12.5 | 38.6 |
| 6 | 0.35 g 1H Benzotriazole | 12.6 | 36.8 |
| 7 | 0.35 g 1H Benzotriazole | 12.6 | 35.7 |
| | and 0.15 g Anox 70 ® | | |
| 8 | 0.35 g Irganox MD 1024 ® | 11.2 | 79.1 |
| | and 0.15 g Tinuvin 123 ® | | |

### Example 3

The concentration of silver in Control #2 and Sample 4 from Example 1 is determined after the 1000 hour exposure. The samples are delaminated. The plasticizer is extracted from the layers by soaking and stirring in a mixture of 75:25 hexane/ethyl acetate. The recovered poly(vinyl butyral) resin retains the color and is then dissolved in acid and analyzed for silver content using a Perkin Elmer Optima 3300 DV instrument. A standard sheet of poly(vinyl butyral) is also analyzed for silver content.

TABLE 3

| | | | Standard |
|---|---|---|---|
| | Control | Sample | poly(vinyl |
| | 2 | 4 | butyral) |
| Ag (ppm) | 316 | 150 | <5 |

The “yellowness index” is measured on intact glass laminates. The sample is measured by hemispherical reflectance with the specular component excluded in accordance with ASTM test method E 1331, and where the clear glass surface faces the light source. Using the reflectance values throughout the visible spectrum, the yellowness index value is calculated using the “C, 1931” column of the “Coefficients of the Equations for Yellowness Index” presented within table 1 of the ASTM E 313 “Standard Test Method for Yellowness Index of Plastics” method.

Testing under bias is accomplished by first forming the following construct: electrode/glass layer/photovoltaic film/electrode/poly(vinyl butyral)/glass layer. A voltage of 1,000 volts direct current is then applied, which results in a current of about 0.1 milliamps.

As shown in the examples, the addition of Tinuvin 328®, a substituted 2H-benzotriazole derivative shown in Formula II, does not prevent yellowing, highlighting the dramatic success of 1H-benzotriazole.

By virtue of the present invention, it is now possible to provide thin film photovoltaic modules having excellent poly(vinyl butyral) stability and resistance to yellowing when employed with photovoltaic devices containing silver.

As shown in Table 4, haze values are shown as a function of the amount of benzotriazole (BTA) in the standard laminate comprising the poly(vinyl butyral) film and 2.3 mm clear glass. The haze values were measured at room temperature of 22° C. immediate after the laminate is produced. The ASTM standard for the haze value test is ASTM D1003-11, Procedure B.

TABLE 4

| | BTA | Haze |
|---|---|---|
| ID | (wt %) | (%) |
| sample 1 | 0.02 | 0.1 |
| sample 2 | 0.2 | 0.2 |
| sample 3 | 0.5 | 0.35 |
| sample 4 | 1.1 | 0.5 |
| sample 5 | 2.2 | 1.1 |

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

It will further be understood that any of the ranges, values, or characteristics given for any single component of the present invention can be used interchangeably with any ranges, values, or characteristics given for any of the other components of the invention, where compatible, to form an embodiment having defined values for each of the components, as given herein throughout. For example, thin film modules can comprise combinations of poly(vinyl butyral) and photovoltaic elements to form many permutations that are within the scope of the present invention, but that would be exceedingly cumbersome to list.

Any Figure reference numbers given within the abstract or any claims are for illustrative purposes only and should not be construed to limit the claimed invention to any one particular embodiment shown in any FIGURE.

Figures are not drawn to scale unless otherwise indicated.

Each reference, including journal articles, patents, applications, and books, referred to herein is hereby incorporated by reference in its entirety.

We claim:

1. A photovoltaic module, comprising:
a base substrate;
a photovoltaic device disposed in contact with said base substrate, wherein said photovoltaic device comprises a metal component;
a poly(vinyl butyral) layer disposed in contact with said photovoltaic device, wherein said poly(vinyl butyral) layer comprises 1H-benzotriazole or 1H-benzotriazole salt; and,
a protective substrate disposed in contact with said poly(vinyl butyral) layer; wherein said poly(vinyl butyral) layer comprises 0.01 to 5 weight percent 1H-benzotriazole or 1H-benzotriazole salt, and wherein the haze value of a standard laminate produced with said poly(vinyl butyral) layer is less than or equal to 0.5%.

2. The module of claim 1, wherein said photovoltaic device is a thin film photovoltaic device.

3. The module of claim 2, wherein said poly(vinyl butyral) layer comprises 0.001 to 5 weight percent 1H-benzotriazole.

4. The module of claim 2, wherein said poly(vinyl butyral) layer comprises 0.1 to 0.4 weight percent 1H-benzotriazole.

5. The module of claim 2, wherein said poly(vinyl butyral) layer comprises 1 to 5 weight percent 1H-benzotriazole.

6. The module of claim 2, wherein said poly(vinyl butyral) layer further comprises a phenolic antioxidant.

7. The module of claim 2, wherein said metal is bismuth, copper, cadmium, lead, tin, zinc, silver, gold, indium, palladium, platinum, aluminum, antimony, chromium, iron, nickel, rhodium, tantalum, titanium, or vanadium.

8. The module of claim 2, wherein said metal is silver.

9. The module of claim 2, wherein said metal component is used as a conductive layer.

10. The interlayer of claim 10, wherein said poly(vinyl butyral) sheet further comprises a phenolic antioxidant.

11. A multilayer laminate comprising
a first substrate;
a metal component disposed in contact with said first substrate;
a poly(vinyl butyral) layer disposed in contact with said metal component, wherein said poly(vinyl butyral) layer comprises 1H-benzotriazole or 1H-benzotriazole salt; and,
a second substrate disposed in contact with said poly(vinyl butyral) layer; wherein the haze value of a standard laminate produced with said poly(vinyl butyral) layer is less than or equal to 0.5%.

12. The multilayer laminate of claim 11, wherein said poly(vinyl butyral) sheet comprises 0.1 to 0.4 weight percent 1H-benzotriazole.

13. The multilayer laminate of claim 11, wherein said poly(vinyl butyral) sheet comprises 1 to 5 weight percent 1H-benzotriazole.

14. The multilayer laminate of claim 11, wherein said poly(vinyl butyral) sheet comprises 0.001 to 5 weight percent 1H-benzotriazole.

15. The multilayer laminate of claim 11, wherein said poly(vinyl butyral) sheet further comprises a phenolic antioxidant.
